(19) United States
(12) Patent Application Publication
(10) Pub. No.: US 2025/0143151 A1
(43) Pub. Date: May 1, 2025

(54) DISPLAY DEVICE

(71) Applicant: Samsung Display Co., LTD., Yongin-si (KR)

(72) Inventors: Jung Hyun KWON, Yongin-si (KR); Hyo Joon KIM, Yongin-si (KR); Keun Young PARK, Yongin-si (KR)

(21) Appl. No.: 18/735,934

(22) Filed: Jun. 6, 2024

(30) Foreign Application Priority Data
Oct. 31, 2023 (KR) 10-2023-0147770

(51) Int. Cl. H10K 59/80; H10K 59/38; H10K 102/00

(52) U.S. Cl. CPC H10K 59/879; H10K 59/38; H10K 59/873; H10K 2102/351

(57) ABSTRACT

A display device includes a light-emitting element layer disposed on a substrate, a thin film encapsulation layer disposed on the light-emitting element layer, a bank disposed on the thin film encapsulation layer, and partitioning emission areas and a non-emission area, a capping layer disposed on the bank, a low refractive layer disposed on the capping layer, and including pores, a passivation layer disposed on the low refractive layer, and defining a plurality of openings, and a color filter layer disposed on the passivation layer, where the low refractive layer overlaps the plurality of openings and includes first regions and a second region different from the first regions, and the first regions contact the color filter layer.

This application claims priority from Korean Patent Application No. 10-2023-0147770, filed on Oct. 31, 2023, and all the benefits accruing therefrom under 35 U.S.C. 119, the contents of which in its entirety are herein incorporated by reference.

### BACKGROUND

### 1. Field

The disclosure relates to a display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light-emitting display device. Examples of the light-emitting display device include an organic light-emitting display device composed of organic light-emitting elements, an inorganic light-emitting display device composed of inorganic light-emitting elements such as inorganic semiconductors, and a micro light-emitting display device composed of micro light-emitting elements.

The organic light-emitting element may include two opposing electrodes, and a light-emitting layer interposed therebetween. The light-emitting layer receives electrons and holes from the two electrodes and recombines the electrons and the holes to generate excitons, and the generated excitons change from an excited state to a ground state, thereby emitting light.

The organic light-emitting display device including organic light-emitting elements is attracting attention as a next-generation display device because of being able to meet the high display quality conditions such as wide viewing angle, high brightness and contrast, and quick response speed as well as being able to be made having a low power consumption, lightweight, and thin due to no necessity of a power source such as a backlight unit.

### SUMMARY

Features of the disclosure provide a display device with improved reliability by overcoming delamination of a low refractive layer.

However, features of the disclosure are not restricted to the one set forth herein. The above and other features of the disclosure will become more apparent to one of ordinary skill in the art to which the disclosure pertains by referencing the detailed description of the disclosure given below.

In an embodiment of the disclosure, a display device includes a light-emitting element layer disposed on a substrate, a thin film encapsulation layer disposed on the light-emitting element layer, a bank disposed on the thin film encapsulation layer, and partitioning emission areas and a non-emission area, a capping layer disposed on the bank, a low refractive layer disposed on the capping layer, and including pores, a passivation layer disposed on the low refractive layer, and defining a plurality of openings, and a color filter layer disposed on the passivation layer, where the low refractive layer overlaps the plurality of openings and includes first regions and a second region different from the first regions, and the first regions contact the color filter layer.

In an embodiment, the first regions may overlap the non-emission area, and the second region may overlap the emission areas.

In an embodiment, the first regions may not include the pores and the second region may include the pores.

In an embodiment, the first regions may have a smaller amount of pores than an amount of pores of the second region.

In an embodiment, the color filter layer may include a first color filter overlapping one of the emission areas and a first color pattern overlapping the non-emission area, and the first regions may contact one of the first color filter and the first color pattern.

In an embodiment, the first regions may include an organic material or colorant of one of the first color filter and the first color pattern.

In an embodiment, the plurality of openings of the passivation layer may overlap the non-emission area.

In an embodiment, the plurality of openings may be defined in a dot shape or mesh shape in a plan view.

In an embodiment of the disclosure, a display device includes a light-emitting element layer disposed on a substrate, a thin film encapsulation layer disposed on the light-emitting element layer, a bank disposed on the thin film encapsulation layer, and partitioning emission areas and a non-emission area, a capping layer disposed on the bank, a low refractive layer disposed on the capping layer, and including pores, a passivation layer disposed on the low refractive layer, and including a first passivation portion and a second passivation portion having a thickness greater than a thickness of the first passivation portion, and a color filter layer disposed on the passivation layer, where the low refractive layer overlaps the first passivation portion and includes first regions which do not include the pores and a second region which includes the pores as a remaining region excluding the first regions.

In an embodiment, the first passivation portion may overlap the non-emission area, and the second passivation portion may overlap the emission areas.

In an embodiment, the thickness of the first passivation portion may range from about 10 nanometers (nm) to about 100 nm.

In an embodiment, the color filter layer may include a first color filter overlapping one of the emission areas and a first color pattern overlapping the non-emission area, and the first regions may overlap one of the first color filter and the first color pattern.

According to a feature of the disclosure, a display device includes a light-emitting element layer disposed on a substrate, a thin film encapsulation layer disposed on the light-emitting element layer, a bank disposed on the thin film encapsulation layer, and partitioning emission areas and a non-emission area, a capping layer disposed on the bank, a low refractive layer disposed on the capping layer, and including pores, a first passivation layer disposed on the low refractive layer, and defining a plurality of openings, an overcoat layer disposed on the first passivation layer, and a color filter layer disposed on the overcoat layer, where the low refractive layer overlaps the plurality of openings and includes first regions and a second region different from the first regions, and the first regions contact the overcoat layer.

In an embodiment, the first regions may not include the pores and the second region may include the pores.

In an embodiment, the first regions may have a smaller amount of pores than an amount of pores of the second region.

In an embodiment, the first regions may include an organic material of the overcoat layer.

In an embodiment, the display device may further include a second passivation layer disposed between the overcoat layer and the color filter layer.

In an embodiment of the disclosure, a display device includes a substrate including a display area and a non-display area, a light-emitting element layer disposed on the display area of the substrate, a thin film encapsulation layer disposed on the light-emitting element layer, a bank disposed on the thin film encapsulation layer, and partitioning emission areas and a non-emission area, a capping layer disposed on the bank, and extending to the non-display area, a low refractive layer disposed on the capping layer, extending from the display area to the non-display area and including pores, a passivation layer disposed on the low refractive layer, and defining a plurality of openings defined in the non-display area, a color filter layer disposed on the display area and the non-display area of the passivation layer, where the low refractive layer overlaps the plurality of openings and includes first regions and a second region different from the first regions, and the first regions contact the color filter layer.

In an embodiment, the plurality of openings may surround the display area, and be defined in a line shape or dot shape in a plan view.

In an embodiment, the first regions may not include the pores and the second region includes the pores.

In an embodiment, the first regions may have a smaller amount of pores than an amount of pores of the second region.

In an embodiment, the first regions may include an organic material of the color filter layer.

In the display device in an embodiment, an opening of a first passivation layer may be formed on the low refractive layer to bring the low refractive layer into contact with a color filter layer or an overcoat layer, thereby removing pores in the low refractive layer and improving an interfacial adhesion property with a capping layer.

In addition, in the display device in an embodiment, a first passivation portion with a relatively small thickness may be formed in the first passivation layer to remove pores in a first region of the low refractive layer overlapping a first color filter and a first color pattern, thereby improving the interfacial adhesion property with the capping layer. Accordingly, the reliability of the display device may be improved by overcoming delamination of the low refractive layer.

However, effects in the embodiments of the disclosure are not limited to those exemplified above and various other effects are incorporated herein.

### BRIEF DESCRIPTION OF THE DRAWINGS

The above and other advantages and features of the disclosure will become more apparent by describing in detail embodiments thereof with reference to the attached drawings, in which:

FIG. 1A is a schematic plan view of an embodiment of a display device, and FIG. 1B is an enlarged view of a dotted portion of FIG. 1A;

FIG. 2 is a cross-sectional view schematically illustrating an embodiment of a display device;

FIG. 3 is a cross-sectional view schematically illustrating an embodiment of a display device;

FIG. 4 is a cross-sectional view schematically illustrating an embodiment of a low refractive layer;

FIGS. 5 to 7 are plan views illustrating an embodiment of various arrangements of openings in a passivation layer;

FIGS. 8 to 10 are cross-sectional views showing an embodiment of various structures of a low refractive layer;

FIG. 11 is a cross-sectional view of another embodiment of a display device;

FIG. 12 is an enlarged cross-sectional view of an embodiment of a partial area of the display device of FIG. 11;

FIG. 13 is a scanning electron microscope (“SEM”) image of a passivation layer;

FIG. 14 is a cross-sectional view showing another embodiment of a display device;

FIG. 15 is a cross-sectional view showing another embodiment of a display device;

FIG. 16 is a cross-sectional view showing another embodiment of a display device;

FIGS. 17 and 18 are plan views showing various embodiments of a display device;

FIG. 19 is a cross-sectional view showing another embodiment of a display device;

FIG. 20 is an SEM image of a low refractive layer manufactured according to a comparative example; and

FIG. 21 is an SEM image of a low refractive layer manufactured according to a test example.

### DETAILED DESCRIPTION

Embodiments of the disclosure will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it may be directly on another layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Each of the features of the various embodiments of the disclosure may be combined or combined with each other, in part or in whole, and technically various interlocking and driving are possible. Each embodiment may be implemented independently of each other or may be implemented together in an association.

Hereinafter, embodiments will be described with reference to the accompanying drawings.

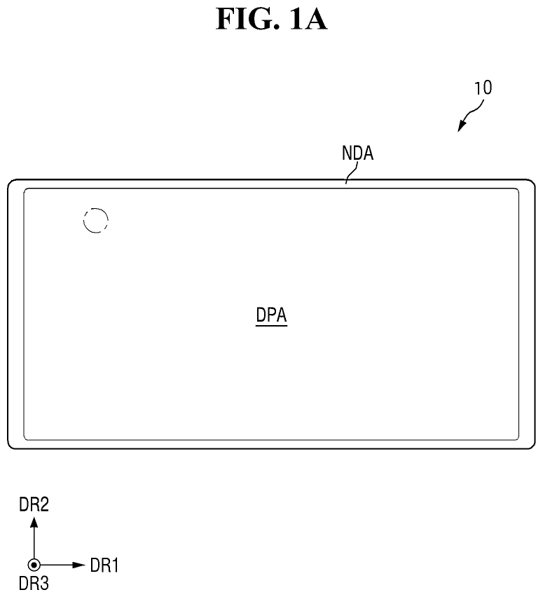

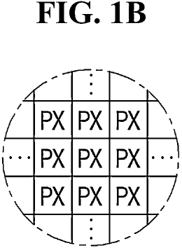

FIG. 1A is a schematic plan view of an embodiment of a display device, and FIG. 1B is an enlarged view of a dotted portion of FIG. 1A.

Referring to FIG. 1A, a display device 10 displays a moving image or a still image. The display device 10 may refer to any electronic device providing a display screen. In embodiments, the display device 10 may include a television, a laptop computer, a monitor, a billboard, an Internet-of-Things device, a mobile phone, a smartphone, a tablet personal computer (“PC”), an electronic watch, a smart watch, a watch phone, a head-mounted display, a mobile communication terminal, an electronic notebook, an electronic book, a portable multimedia player (“PMP”), a navigation device, a game machine, a digital camera, a camcorder or the like, which provide a display screen.

The display device 10 may include a display panel which provides a display screen. In embodiments, the display panel may include an inorganic light-emitting diode display panel, an organic light-emitting display panel, a quantum dot light-emitting display panel, a plasma display panel and a field emission display panel. In the following description, a case where an organic light-emitting diode or inorganic light-emitting diode display panel is applied as a display panel will be exemplified, but the disclosure is not limited thereto, and other display panels may be applied within the same scope of technical spirit.

Hereinafter, a first direction DR1, a second direction DR2, and a third direction DR3 are defined in drawings of an embodiment describing the display device 10. The first direction DR1 and the second direction DR2 may be directions perpendicular to each other in one plane. The third direction DR3 may be a direction perpendicular to a plane on which the first direction DR1 and the second direction DR2 are extended. The third direction DR3 is perpendicular to each of the first direction DR1 and the second direction DR2. In the embodiment describing the display device 10, the third direction DR3 indicates a thickness direction of the display device 10.

The display device 10 may have a quadrangular shape, e.g., rectangular shape including long and short sides such that the side in the first direction DR1 is longer than the side in the second direction DR2 in a plan view. A corner portion where the long side and the short side of the display device 10 meet may be right-angled in a plan view. However, the disclosure is not limited thereto, and the corner portion may be rounded to have a curved shape. The planar shape of the display device 10 is not limited to the illustrated example, and may be other shapes such as a square shape, a quadrilateral shape with rounded corners (vertices), other polygonal shapes and a circular shape.

A display surface of the display device 10 may be disposed on one side of the third direction DR3 which is the thickness direction. In an embodiment describing the display device 10, unless otherwise noted, the term “upward” refers to one side of the third direction DR3, which is the display direction, and the term “top surface” refers to a surface toward the one side of the third direction DR3. Further, the term “downward” refers to an opposite side of the third direction DR3, which is an opposite direction to the display direction, and the term “bottom surface” refers to a surface toward an opposite side of the third direction DR3. Furthermore, “left”, “right”, “upper” and “lower” indicate directions when the display device 10 is viewed from above. In an embodiment, “right side” indicates one side of the first direction DR1, “left side” indicates an opposite side of the first direction DR1, “upper side” indicates one side of the second direction DR2, and “lower side” indicates an opposite side of the second direction DR2.

The display device 10 may include a display area DPA and a non-display area NDA. The display area DPA is an area where a screen may be displayed, and the non-display area NDA is an area where a screen is not displayed. The display area DPA may also be referred to as an active region, and the non-display area NDA may also be also referred to as a non-active region.

The shape of the display area DPA may follow the shape of the display device 10. In an embodiment, the shape of the display area DPA may have a quadrangular shape, e.g., rectangular shape similar to the overall shape of the display device 10 in a plan view, for example. The display area DPA may substantially occupy the center of the display device 10.

The display area DPA may include a plurality of pixels PX as illustrated in FIG. 1B. The plurality of pixels PX may be defined in a matrix. The shape of each pixel PX may be a quadrangular shape, e.g., rectangular or square shape in a plan view. However, the disclosure is not limited thereto, and the shape of each pixel PX may be a rhombic shape in which each side is inclined with respect to one direction. The pixels PX may be disposed in a stripe type or a PenTile™ type. In addition, each of the pixels PX may include one or more light-emitting elements that emit light of a predetermined wavelength band to display a predetermined color.

The non-display area NDA may be disposed around the display area DPA. The non-display area NDA may completely or partially surround the display area DPA. The display area DPA may have a quadrangular shape, e.g., rectangular shape, and the non-display area NDA may be disposed adjacent to four sides of the display area DPA. The non-display area NDA may form a bezel of the display device 10. Wirings or circuit drivers included in the display device 10 may be disposed in the non-display area NDA, or external devices may be disposed (e.g., mounted) thereon.

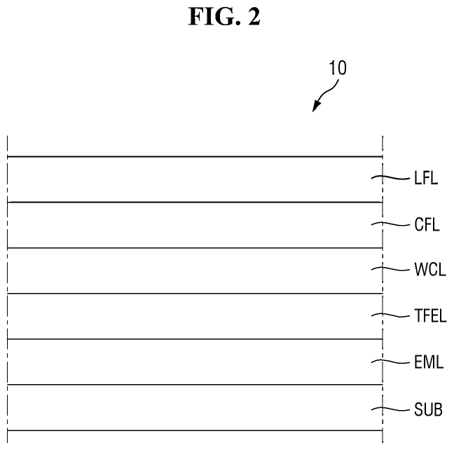

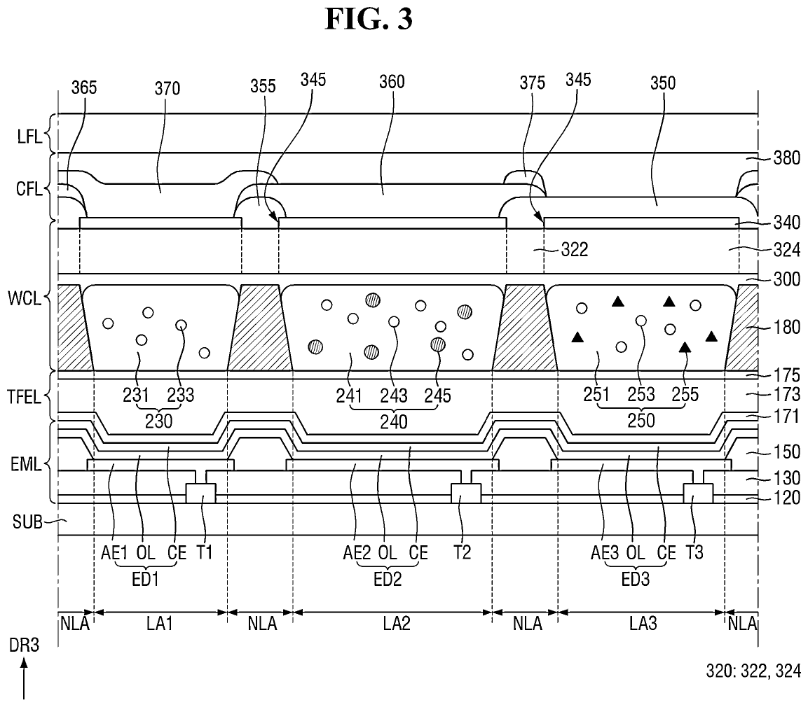

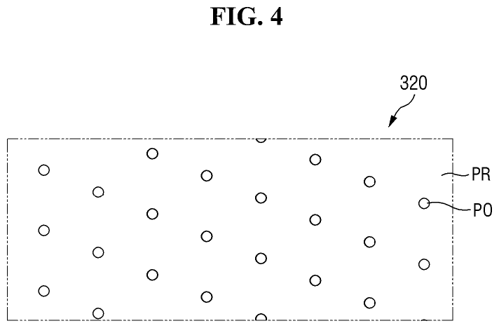

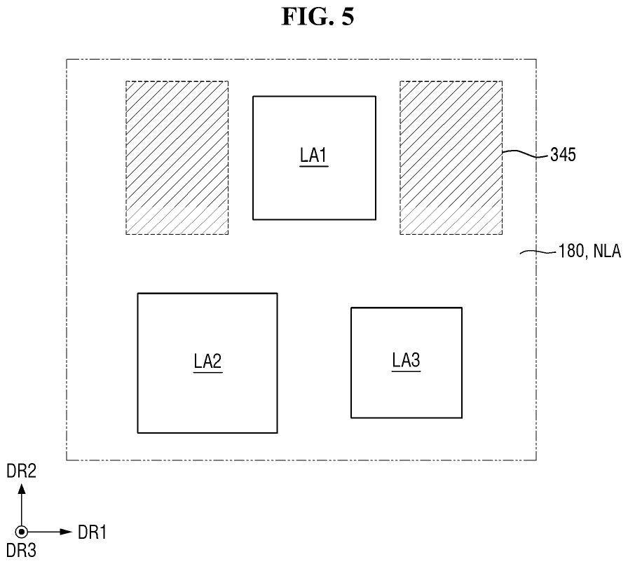

FIG. 2 is a cross-sectional view schematically illustrating an embodiment of a display device. FIG. 3 is a cross-sectional view schematically illustrating an embodiment of a display device. FIG. 4 is a schematic cross-sectional view of an embodiment of a low refractive layer. FIGS. 5 to 7 are plan views illustrating an embodiment of various arrangements of openings in a passivation layer.

FIG. 3 shows a cross-sectional structure of a plurality of emission areas LA1, LA2, and LA3 of the display device 10.

Referring to FIGS. 2 to 4, the display device 10 may include a substrate SUB, a light-emitting element layer EML, a thin film encapsulation layer TFEL, a wavelength conversion layer WCL, a color filter layer CFL, and an optical functional layer LFL.

The substrate SUB may be an insulating substrate. The substrate SUB may include a transparent material. In an embodiment, the substrate SUB may include a transparent insulating material such as glass, quartz, or the like, for example. The substrate SUB may be a rigid substrate. However, the substrate SUB is not limited thereto. The substrate SUB may include plastic such as polyimide or the like, and may have a flexible property such that the substrate SUB may be twisted, bent, folded, or rolled. The plurality of emission areas LA1, LA2, and LA3 and a non-emission area NLA may be defined in the substrate SUB.

The emission areas LA1, LA2, and LA3 may be areas where light generated by the light-emitting elements ED1, ED2, and ED3 is emitted to the outside, and the non-emission area NLA may be an area where no light is emitted to the outside. In an embodiment, a first emission area LA1, a second emission area LA2, and a third emission area LA3 may be sequentially and repeatedly disposed along the first direction DR1 in the display area DPA. The widths of the first emission area LA1, the second emission area LA2, and the third emission area LA3 measured in the first direction DR1 may be the same or different from each other.

The emission areas LA1, LA2, and LA3 may emit light of different colors. In an embodiment, the first emission area LA1 may emit light of a first color, the second emission area LA2 may emit light of a second color, and the third emission area LA3 may emit light of a third color. In an embodiment, the light of the first color may be blue light having a peak wavelength in a range of about 440 nanometers (nm) to about 480 nm, and the light of the second color may be red light having a peak wavelength in a range of about 610 nm to about 650 nm. In addition, the light of the third color may be green light having a peak wavelength in a range of about 510 nm to about 550 nm. However, the disclosure is not limited thereto, and the light of the second color may be green light and the light of the third color may be red light.

Switching elements T1, T2, and T3 may be disposed on the substrate SUB. In an embodiment, a first switching element T1 may be disposed in the first emission area LA1 of the substrate SUB, a second switching element T2 may be disposed in the second emission area LA2 thereof, and a third switching element T3 may be disposed in the third emission area LA3 thereof. However, the disclosure is not limited thereto, and in another embodiment, at least one of the first switching element T1, the second switching element T2, or the third switching element T3 may be disposed in the non-emission area NLA.

In an embodiment, each of the first switching element T1, the second switching element T2, and the third switching element T3 may be a thin film transistor including amorphous silicon, polysilicon, or an oxide semiconductor. In addition, although not shown in the drawing, a plurality of signal lines (e.g., a gate line, a data line, a power line, or the like) that transmit signals to the switching elements may be further disposed on the substrate SUB. Further, each of the switching elements T1, T2, and T3 may include a first insulating layer 120. In an embodiment, the first insulating layer 120 may be a gate insulating layer or an inter-insulating layer of a thin film transistor, for example. The gate insulating layer or the inter-insulating layer may be formed as a single layer including or consisting of any one of silicon oxide (SiOx), silicon nitride oxide (SiOxNy), and silicon nitride (SiNx), or a multilayer thereof.

A second insulating layer 130 may be disposed on the first switching element T1, the second switching element T2 and the third switching element T3. In an embodiment, the second insulating layer 130 may be a planarization layer. In an embodiment, the second insulating layer 130 may include or consist of an organic layer. In an embodiment, the second insulating layer 130 may include acrylic resin, epoxy resin, imide resin, ester resin, or the like. In an embodiment, the second insulating layer 130 may include a positive photosensitive material or a negative photosensitive material, for example.

A first anode electrode AE1, a second anode electrode AE2, and a third anode electrode AE3 may be disposed on the second insulating layer 130. The first anode electrode AE1 may be disposed in the first emission area LA1, but at least a part thereof may extend to the non-emission area NLA. The second anode electrode AE2 may be disposed in the second emission area LA2, but at least a part thereof may extend to the non-emission area NLA. The third anode electrode AE3 may be disposed in the third emission area LA3, but at least a part thereof may extend to the non-emission area NLA. The first anode electrode AE1 may be connected to the first switching element T1 through the second insulating layer 130, and the second anode electrode AE2 may be connected to the second switching element T2 through the second insulating layer 130. The third anode electrode AE3 may be connected to the third switching element T3 through the second insulating layer 130.

In an embodiment, the widths or areas of the first anode electrode AE1, the second anode electrode AE2 and the third anode electrode AE3 may be different from each other. In an embodiment, the width of the first anode electrode AE1 may be smaller than the width of the second anode electrode AE2, and the width of the third anode electrode AE3 may be smaller than the width of the second anode electrode AE2 and larger than the width of the first anode electrode AE1, for example. In an alternative embodiment, the area of the first anode electrode AE1 may be smaller than the area of the second anode electrode AE2, and the area of the third anode electrode AE3 may be smaller than the area of the second anode electrode AE2 and larger than the area of the first anode electrode AE1. In an alternative embodiment, the area of the first anode electrode AE1 may be smaller than the area of the second anode electrode AE2, and the area of the third anode electrode AE3 may be larger than the area of the second anode electrode AE2 and the area of the first anode electrode AE1. However, the disclosure is not limited to the above-described embodiment. In another embodiment, the widths or areas of the first anode electrode AE1, the second anode electrode AE2 and the third anode electrode AE3 may be substantially the same.

The first anode electrode AE1, the second anode electrode AE2, and the third anode electrode AE3 may be reflective electrodes. The first anode electrode AE1, the second anode electrode AE2, and the third anode electrode AE3 may have a stacked structure formed by stacking a material layer having a relatively high work function, such as indium tin oxide (“ITO”), indium zinc oxide (“IZO”), zinc oxide (ZnO) and indium oxide (In₂O₃), and a reflective material layer such as silver (Ag), magnesium (Mg), aluminum (Al), platinum (Pt), lead (Pb) gold (Au), nickel (Ni), neodymium (Nd), iridium (Ir), chromium (Cr), lithium (Li), calcium (Ca), or any combinations thereof. The material layer having a relatively high work function may be disposed above the reflective material layer and disposed closer to a light-emitting layer OL. The first anode electrode AE1, the second anode electrode AE2, and the third anode electrode AE3 may have a multilayer structure of ITO/Mg, ITO/MgF, ITO/Ag, and ITO/Ag/ITO, but the disclosure is not limited thereto.

A pixel defining layer 150 may be disposed on the first anode electrode AE1, the second anode electrode AE2 and the third anode electrode AE3. The pixel defining layer 150 may define an opening exposing the first anode electrode AE1, an opening exposing the second anode electrode AE2 and an opening exposing the third anode electrode AE3, and may define the first emission area LA1, the second emission area LA2, the third emission area LA3 and the non-emission area NLA. That is, a region of the first anode electrode AE1 which is exposed without being covered by the pixel defining layer 150 may be the first emission area LA1. A region of the second anode electrode AE2 which is exposed without being covered by the pixel defining layer 150 may be the second emission area LA2. A region of the third anode electrode AE3 which is exposed without being covered by the pixel defining layer 150 may be the third emission area LA3. In addition, a region where the pixel defining layer 150 is disposed may be the non-emission area NLA.

The pixel defining layer 150 may include an organic insulating material such as acrylic resin, epoxy resin, phenolic resin, polyamide resin, polyimide resin, unsaturated polyester resin, polyphenylene resin, polyphenylenesulfide resin or benzocyclobutene (“BCB”).

In an embodiment, the pixel defining layer 150 may overlap a bank 180 of the wavelength conversion layer WCL, which will be described later. The light-emitting layer OL may be disposed on the first anode electrode AE1, the second anode electrode AE2 and the third anode electrode AE3. In an embodiment in which the display device 10 is an organic light-emitting display, the light-emitting layer OL may include an organic layer having an organic material. The organic layer may have an organic light-emitting layer, and in some cases, may further have at least one of a hole injection layer, a hole transport layer, an electron transport layer, or an electron injection layer as an auxiliary layer for light emission. In an embodiment, the light-emitting layer OL may have a tandem structure in which a plurality of organic light-emitting layers are superposed in the thickness direction and a charge generation layer is disposed between the organic light-emitting layers. The respective organic light-emitting layers superposed may emit light of the same wavelength, or may emit light of different wavelengths.

In an embodiment, the light-emitting layer OL may have a shape of a continuous film formed over the plurality of emission areas LA1, LA2, and LA3 and the non-emission area NLA. In this case, the wavelength of light emitted from the light-emitting layer OL may be the same. In an embodiment, the light-emitting layer OL may emit blue light or ultraviolet light in the plurality of emission areas LA1, LA2, and LA3, for example.

A cathode electrode CE may be disposed on the light-emitting layer OL. In an embodiment, the cathode electrode CE may have a semi-transmissive or transmissive property. When the cathode electrode CE has a semi-transmissive property, the cathode electrode CE may include Ag, Mg, Cu, Al, Pt, Pd, Au, Ni, Nd, Ir, Cr, Li, Ca, LiF/Ca, LiF/Al, Mo, Ti or a compound or combination thereof, such as a combination of Ag and Mg. In addition, when the cathode electrode CE has a thickness of tens to hundreds of angstroms, the cathode electrode CE may have a semi-transmissive property.

When the cathode electrode CE has a transmissive property, the cathode electrode CE may include a transparent conductive oxide (“TCO”). In an embodiment, the cathode electrode CE may include tungsten oxide (WxOy), titanium oxide (TiO₂), indium tin oxide (“ITO”), indium zinc oxide (“IZO”), zinc oxide (ZnO), indium tin zinc oxide (“ITZO”), magnesium oxide (MgO) or the like, for example.

The first anode electrode AE1, the light-emitting layer OL and the cathode electrode CE may constitute a first light-emitting element ED1. The second anode electrode AE2, the light-emitting layer OL and the cathode electrode CE may constitute a second light-emitting element ED2. The third anode electrode AE3, the light-emitting layer OL and the cathode electrode CE may constitute a third light-emitting element ED3. The first light-emitting element ED1, the second light-emitting element ED2, and the third light-emitting element ED3 may each emit source light, and the source light may be provided to the wavelength conversion layer WCL. The source light may be blue light, for example, but is not limited thereto. Each of the first light-emitting element ED1, the second light-emitting element ED2, and the third light-emitting element ED3 may be an organic light-emitting diode.

The thin film encapsulation layer TFEL may be disposed on the cathode electrode CE. The thin film encapsulation layer TFEL is commonly disposed in the first emission area LA1, the second emission area LA2, the third emission area LA3, and the non-emission area NLA. In an embodiment, the thin film encapsulation layer TFEL may directly cover the cathode electrode CE.

In an embodiment, the thin film encapsulation layer TFEL may include a first encapsulation inorganic layer 171, an encapsulation organic layer 173 and a second encapsulation inorganic layer 175 sequentially stacked on the cathode electrode CE.

Each of the first encapsulation inorganic layer 171 and the second encapsulation inorganic layer 175 may include or consist of one or more of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, and lithium fluoride. The encapsulation organic layer 173 may include acrylic resin, methacrylate resin, polyisoprene, vinyl resin, epoxy resin, urethane resin, cellulose resin, perylene resin, or the like.

However, the structure of the thin film encapsulation layer TFEL is not limited to the above-described example. In addition, the stacked structure of the thin film encapsulation layer TFEL may be variously changed.

The wavelength conversion layer WCL may be disposed on the light-emitting element layer EML including the thin film encapsulation layer TFEL.

The wavelength conversion layer WCL may include the bank 180, a light transmission pattern 230, a first wavelength conversion pattern 240, a second wavelength conversion pattern 250, a capping layer 300, a low refractive layer 320, and a first passivation layer 340.

The bank 180 may be disposed on the thin film encapsulation layer TFEL. The bank 180 may partition the emission areas LA1, LA2, and LA3 and the non-emission area NLA. The bank 180 may be disposed to overlap the non-emission area NLA and may block the transmission of light. More specifically, the bank 180 may be disposed between the light transmission pattern 230 and the first wavelength conversion pattern 240 and between the first wavelength conversion pattern 240 and the second wavelength conversion pattern 250 to prevent color mixing between adjacent emission areas.

The bank 180 may include an organic light-blocking material, and may be formed through an inkjet method or a coating and exposure process of an organic light-blocking material. In an embodiment, the bank 180 may include an organic material and a dye or pigment having a light-blocking property mixed in the organic material, for example. The organic material may include acrylic resin, methacrylate resin, polyisoprene, vinyl resin, epoxy resin, urethane resin, cellulose resin, perylene resin, or the like. The dye or pigment may include carbon black or the like.

The light transmission pattern 230 may be disposed on the thin film encapsulation layer TFEL. In an embodiment, the light transmission pattern 230 may be formed by applying a photosensitive material and exposing and developing the photosensitive material. However, the disclosure is not limited thereto, and the light transmission pattern 230, the first wavelength conversion pattern 240, and the second wavelength conversion pattern 250 may be formed using an inkjet method.

The light transmission pattern 230 may overlap the first emission area LA1. The light transmission pattern 230 may transmit incident light. The source light provided from the first light-emitting element ED1 may be blue light as described above. The source light, which is blue light, may pass through the light transmission pattern 230.

In an embodiment, the light transmission pattern 230 may include a first base resin 231 and may further include a first scatterer 233 dispersed in the first base resin 231.

The first base resin 231 may include or consist of a material with relatively high light transmittance. In an embodiment, the first base resin 231 may include or consist of an organic material. In an embodiment, the first base resin 231 may include an organic material such as epoxy resin, acrylic resin, cardo resin, or imide resin, for example.

The first scatterer 233 may have a refractive index different from that of the first base resin 231 and may form an optical interface with the first base resin 231. In an embodiment, the first scatterer 233 may be light scattering particles, for example. The first scatterer 233 is not particularly limited as long as it is a material capable of scattering at least a portion of the transmitted light, but may be metal oxide particles or organic particles, for example. In embodiments, the metal oxide may include titanium oxide (TiO₂), zirconium oxide (ZrO₂), aluminum oxide (Al₂O₃), indium oxide (In₂O₃), zinc oxide (ZnO), tin oxide (SnO₂), or the like. In embodiments, a material of the organic particles may include acrylic resin and urethane resin, or the like. The first scatterer 233 may scatter light in a random direction irrespective of the incident direction of incident light, without substantially converting the wavelength of the light passing through the light transmission pattern 230.

The first wavelength conversion pattern 240 and the second wavelength conversion pattern 250 may be disposed on the thin film encapsulation layer TFEL.

The first wavelength conversion pattern 240 may be disposed on the thin film encapsulation layer TFEL and may overlap the second emission area LA2. The first wavelength conversion pattern 240 may emit light by converting or shifting the peak wavelength of incident light to another predetermined peak wavelength. In an embodiment, the first wavelength conversion pattern 240 may convert the source light provided from the second light-emitting element ED2 into red light having a peak wavelength in a range of about 610 nm to about 650 nm and emit the red light.

The first wavelength conversion pattern 240 may include a second base resin 241 and a first wavelength shifter 245 dispersed in the second base resin 241, and may further include a second scatterer 243 dispersed in the second base resin 241.

The second base resin 241 may include or consist of a material having relatively high light transmittance. In an embodiment, the second base resin 241 may include or consist of an organic material. The second base resin 241 may include or consist of the same material as that of the first base resin 231, or may include at least one of the materials exemplified as the constituent materials of the first base resin 231.

The first wavelength shifter 245 may convert or shift the peak wavelength of incident light to another predetermined peak wavelength. In an embodiment, the first wavelength shifter 245 may convert light of the first color, which is blue light, provided from the second light-emitting element ED2 into red light having a single peak wavelength in a range of about 610 nm to about 650 nm, and may emit it.

In embodiments, the first wavelength shifter 245 may include a quantum dot, a quantum rod, a phosphor, or the like. In an embodiment, a quantum dot may be a particulate material that emits light of a predetermined color when an electron transitions from a conduction band to a valence band, for example.

The quantum dot may be a semiconductor nanocrystal material. The quantum dot may have a predetermined band gap according to its composition and size. Thus, the quantum dot may absorb light and then emit light having an intrinsic wavelength. In embodiments, semiconductor nanocrystal of quantum dots may include group IV nanocrystal, group II-VI compound nanocrystal, group III-V compound nanocrystal, group IV-VI nanocrystal, any combinations thereof, or the like.

The group II-VI compound may be selected from the group consisting of binary compounds, ternary compounds, and quaternary compounds, where the binary compounds are selected from the group consisting of CdSe, CdTe, ZnS, ZnSe, ZnTe, ZnO, HgS, HgSe, HgTe, MgSe, MgS and combinations thereof, the ternary compounds are selected from the group consisting of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and combinations thereof, and the quaternary compounds are selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and combinations thereof.

The group III-V compound may be selected from the group consisting of binary compounds, ternary compounds, and quaternary compounds, where the binary compounds are selected from the group consisting of GaN, GaP, GaAs, GaSb, AlN, AlP, AlAs, AlSb, InN, InP, InAs, InSb and combinations thereof, the ternary compounds are selected from the group consisting of GaNP, GaNAs, GaNSb, GaPAs, GaPSb, AlNP, AlNAs, AlNSb, AlPAS, AlPSb, InGaP, InNP, InAIP, InNAs, InNSb, InPAs, InPSb, GaAlNP and combinations thereof, and the quaternary compounds are selected from the group consisting of GaAlNAs, GaAlNSb, GaAlPAs, GaAlPSb, GalnNP, GalnNAs, GalnNSb, GalnPAs, GalnPSb, InAlNP, InAlNAs, InAlNSb, InAlPAs, InAlPSb and combinations thereof.

The group IV-VI compound may be selected from the group consisting of binary compounds, ternary compounds, and quaternary compounds, where the binary compounds are selected from the group consisting of SnS, SnSe, SnTe, PbS, PbSe, PbTe and combinations thereof, the ternary compounds are selected from the group consisting of SnSeS, SnSeTe, SnSTe, PbSeS, PbSeTe, PbSTe, SnPbS, SnPbSe, SnPbTe and combinations thereof, and the quaternary compounds are selected from the group consisting of SnPbSSe, SnPbSeTe, SnPbSTe and combinations thereof. The group IV element may be selected from the group consisting of Si, Ge and combinations thereof. The group IV compound may be a binary compound selected from the group consisting of SiC, SiGe and combinations thereof.

In this case, the binary compound, the tertiary compound or the quaternary compound may exist in particles at a uniform concentration, or may exist in the same particle divided into states where concentration distributions are partially different. Further, the particles may have a core/shell structure in which one quantum dot surrounds another quantum dot. An interface between the core and the shell may have a concentration gradient in which the concentration of elements in the shell decreases toward the center.

In an embodiment, the quantum dot may have a core-shell structure including a core including the nanocrystal described above and a shell surrounding the core. The shell of the quantum dot may serve as a protective layer for maintaining semiconductor characteristics by preventing chemical denaturation of the core and/or as a charging layer for giving electrophoretic characteristics to the quantum dot. The shell may be a single layer or a multilayer. In embodiments, the shell of the quantum dot may include a metal or non-metal oxide, a semiconductor compound, or any combinations thereof.

In an embodiment, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, or a tertiary compound such as MgAl₂O₄, CoFe₂O₄, NiFe₂O₄ and CoMn₂O₄, for example, but the disclosure is not limited thereto.

In addition, the semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb or the like, for example, but is not limited thereto.

The light emitted from the first wavelength shifter 245 may have a full width at half maximum (“FWHM”) of the emission wavelength spectrum, which is about 45 nm or less, about 40 nm or less, or about 30 nm or less. Thus, the purity and reproducibility of colors displayed by the display device 10 may be further improved. In addition, the light emitted from the first wavelength shifter 245 may be emitted in various directions regardless of the incident direction of incident light. Accordingly, side visibility of the second color displayed in the second emission area LA2 may be improved.

Portion of the source light provided from the second light-emitting element ED2 may not be converted into red light by the first wavelength shifter 245. However, the source light that has not been converted into red light may be blocked by the color filter layer CFL disposed thereabove. The source light that has been converted into red light by the first wavelength conversion pattern 240 passes through the color filter layer CFL and is emitted to the outside.

The second scatterer 243 may have a refractive index different from that of the second base resin 241 and form an optical interface with the second base resin 241. In an embodiment, the second scatterer 243 may be light scattering particles, for example. A more detailed description of the second scatterer 243 is substantially the same as or similar to the description of the first scatterer 233, and thus will be omitted.

The second wavelength conversion pattern 250 may be disposed on the thin film encapsulation layer TFEL and may overlap the third emission area LA3. The second wavelength conversion pattern 250 may emit light by converting or shifting the peak wavelength of incident light to another predetermined peak wavelength. In an embodiment, the second wavelength conversion pattern 250 may convert the source light provided from the third light-emitting element ED3 into green light having a peak wavelength of about 510 nm to about 550 nm and emit the green light.

The second wavelength conversion pattern 250 may include a third base resin 251 and a second wavelength shifter 255 dispersed in the third base resin 251, and may further include a third scatterer 253 dispersed in the third base resin 251.

The third base resin 251 may include or consist of a material having relatively high light transmittance. In an embodiment, the third base resin 251 may include or consist of an organic material. The third base resin 251 may include or consist of the same material as that of the first base resin 231, or may include at least one of the materials exemplified as the constituent materials of the first base resin 231.

The second wavelength shifter 255 may convert or shift the peak wavelength of incident light to another predetermined peak wavelength. In an embodiment, the second wavelength shifter 255 may convert blue light having a peak wavelength in a range of about 440 nm to about 480 nm into green light having a peak wavelength in a range of about 510 nm to about 550 nm.

In embodiments, the second wavelength shifter 255 may include a quantum dot, a quantum rod, a phosphor, or the like. A more detailed description of the second wavelength shifter 255 is substantially the same as or similar to the description of the first wavelength shifter 245, and thus will be omitted. In an embodiment, both the first wavelength shifter 245 and the second wavelength shifter 255 may include or consist of quantum dots. In this case, the particle size of the quantum dots forming the first wavelength shifter 245 may be larger than the particle size of the quantum dots forming the second wavelength shifter 255.

The third scatterer 253 may have a refractive index different from that of the third base resin 251 and form an optical interface with the third base resin 251. In an embodiment, the third scatterer 253 may be light scattering particles, for example. A more detailed description of the third scatterer 253 is substantially the same as or similar to the description of the second scatterer 243, and thus will be omitted.

The source light emitted from the third light-emitting element ED3 may be provided to the second wavelength conversion pattern 250, and the second wavelength shifter 255 may convert the source light provided from the third light-emitting element ED3 to green light having a peak wavelength in the range of about 510 nm to about 550 nm and emit the green light.

Portion of the source light, which is blue light, may not be converted into green light by the second wavelength shifter 255 and may pass through the second wavelength conversion pattern 250. However, light that has not been converted into green light may be blocked by the color filter layer CFL. The source light that has been converted into green light by the second wavelength conversion pattern 250 passes through the color filter layer CFL and is emitted to the outside.

The capping layer 300 may be disposed on the bank 180, the light transmission pattern 230, the first wavelength conversion pattern 240, and the second wavelength conversion pattern 250 to cover them. Accordingly, the capping layer 300 may prevent contamination or damage of the bank 180, the light transmission pattern 230, the first wavelength conversion pattern 240 and the second wavelength conversion pattern 250 due to infiltration of impurities such as moisture or air from the outside.

The capping layer 300 may include or consist of an inorganic material. In an embodiment, the capping layer 300 may include silicon nitride, aluminum nitride, zirconium nitride, titanium nitride, hafnium nitride, tantalum nitride, silicon oxide, aluminum oxide, titanium oxide, tin oxide, silicon oxynitride, or the like, for example.

The low refractive layer 320 may be disposed on the capping layer 300. The low refractive layer 320 may be disposed directly on the capping layer 300. The low refractive layer 320 may be entirely disposed in the display area DPA (refer to FIG. 1A) of the display device 10. In an embodiment, the low refractive layer 320 may be disposed on the emission areas LA1, LA2, and LA3 and the non-emission area NLA in the display area, for example. The low refractive layer 320 may have a refractive index that is relatively lower than those of the light transmission pattern 230, the first wavelength conversion pattern 240, the second wavelength conversion pattern 250, and the capping layer 300, and may serve to improve light output efficiency by allowing light emitted from its lower portion to be refracted to its upper portion due to the difference in refractive index.

The low refractive layer 320 may include pores PO dispersed in a transparent resin PR. The resin PR may include one or more selected from the group including acrylic, polysiloxane, polyurethane, polyurethane acrylate, polyimide, polymethylsilsesquioxane (“PMSSQ”), and polymethyl methacrylate (“PMMA”).

The pore PO may be a hole including or consisting of air and may be randomly dispersed in the resin PR. The top and bottom surfaces of the low refractive layer 320 may include flat areas and may also include uneven areas due to the pores PO. The pores PO may function to reduce the refractive index of the low refractive layer 320 due to air having a refractive index of 1.

Additionally, the low refractive layer 320 may further include hollow particles. The hollow particle may include one or more selected from the group including silica (SiO₂), magnesium fluoride (MgF₂), and iron oxide (Fe₃O₄). In an embodiment, the hollow particle may include a shell including or consisting of one or more of the above materials and a hollow in the shell, for example. In an embodiment, the diameter of the hollow particle may range from about 20 nm to about 200 nm, but is not limited thereto.

The first passivation layer 340 may be disposed on the low refractive layer 320. The first passivation layer 340 may be directly disposed on the low refractive layer 320 to cover the low refractive layer 320. The first passivation layer 340 may cover the low refractive layer 320 to prevent damage or contamination of the low refractive layer 320.

The first passivation layer 340 may include or consist of an inorganic material. In an embodiment, the capping layer 300 may include silicon nitride, aluminum nitride, zirconium nitride, titanium nitride, hafnium nitride, tantalum nitride, silicon oxide, aluminum oxide, titanium oxide, tin oxide, silicon oxynitride, or the like, for example. The thickness of the first passivation layer 340 may range from about 100 nm to about 1000 nm, but is not limited thereto.

In an embodiment, a plurality of openings 345 may be defined in the first passivation layer 340. The plurality of openings 345 may penetrate the first passivation layer 340 to expose the low refractive layer 320 therebelow. The plurality of openings 345 may not overlap the first to third emission areas LA1, LA2, and LA3, and may be defined to overlap the non-emission area NLA. The plurality of openings 345 may be defined to overlap the bank 180 of the wavelength conversion layer WCL.

As shown in FIG. 5, the plurality of openings 345 may be defined so as not to overlap the first to third emission areas LA1, LA2, and LA3 in areas overlapping the non-emission area NLA and the bank 180. The plurality of openings 345 may be spaced apart from each other to form an island shape. In an embodiment, the plurality of openings 345 may be defined to be spaced apart from each other to the left and right sides of the first emission area LA1, for example.

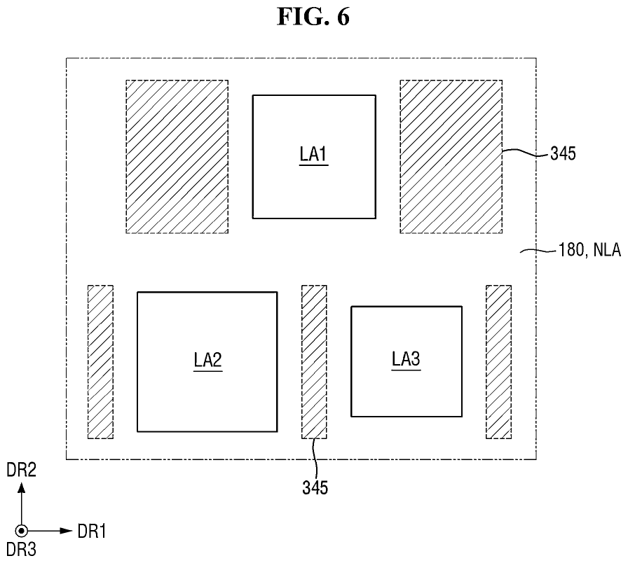

Further, as shown in FIG. 6, the plurality of openings 345 may be defined to be spaced apart from each other to one side of the second emission area LA2, between the second emission area LA2 and the third emission area LA3, and to one side of the third emission area LA3.

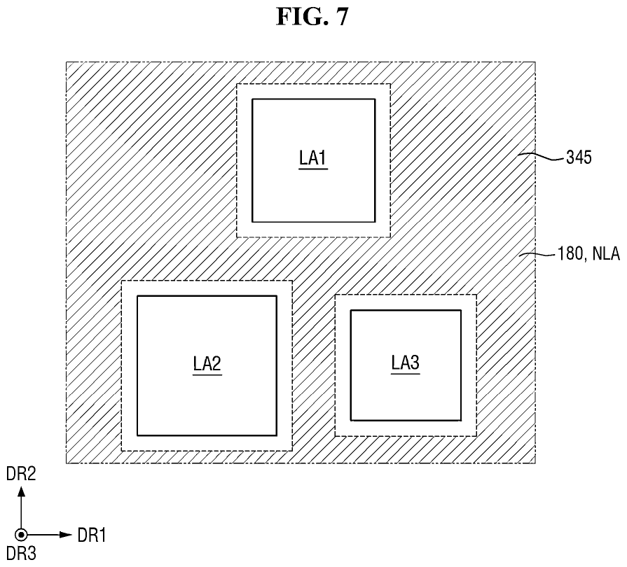

As shown in FIG. 7, the plurality of openings 345 may have a mesh shape. In this case, the plurality of openings 345 may have substantially the same shape as that of the bank 180 in a plan view.

Referring back to FIG. 3, the color filter layer CFL may be disposed on the wavelength conversion layer WCL. The color filter layer CFL may include a first color filter 350, a second color filter 360, and a third color filter 370. In addition, the color filter layer CFL may include a first color pattern 355, a second color pattern 365, and a third color pattern 375.

The first color filter 350 may be disposed on the first passivation layer 340 to overlap the third emission area LA3. The first color filter 350 may be disposed to overlap the third light-emitting element ED3 and the second wavelength conversion pattern 250. The first color pattern 355 may be spaced apart from the first color filter 350 and overlap the non-emission area NLA. The first color filter 350 and the first color pattern 355 may be in direct contact with the low refractive layer 320 exposed by the opening 345 of the first passivation layer 340.

The first color filter 350 and the first color pattern 355 may selectively allow the third color light (e.g., green light) to pass therethrough, and may block or absorb the first color light (e.g., blue light) and the second color light (e.g., red light). In an embodiment, the first color filter 350 may be a green color filter and may include a green colorant such as a green dye or green pigment. In the specification, the colorant is the concept including both a dye and a pigment.

The second color filter 360 may overlap the second emission area LA2, and may overlap the second light-emitting element ED2 and the first wavelength conversion pattern 240. In an embodiment, one side of the second color filter 360 may overlap the non-emission area NLA, and may overlap the first color filter 350 adjacent thereto. An opposite side of the second color filter 360 may overlap the non-emission area NLA and the first color pattern 355. The second color pattern 365 may be spaced apart from the second color filter 360 and overlap the non-emission area NLA. The second color pattern 365 may be disposed to overlap the first color filter 350 in the non-emission area NLA.

The second color filter 360 and the second color pattern 365 may selectively allow the second color light (e.g., red light) to pass therethrough, and may block or absorb the first color light (e.g., blue light) and the third color light (e.g., green light). In an embodiment, the second color filter 360 may be a red color filter and may include a red colorant such as red dye or red pigment, for example.

The third color filter 370 may overlap the first emission area LA1, and may overlap the first light-emitting element ED1, and the light transmission pattern 230. In an embodiment, one side of the third color filter 370 may overlap the non-emission area NLA and may overlap the second color filter 360 adjacent thereto. Further, an opposite side of the third color filter 370 may overlap the non-emission area NLA, and may overlap the second color pattern 365 and the first color filter 350 adjacent thereto. The third color pattern 375 may be spaced apart from the third color filter 370 and overlap the non-emission area NLA. The third color pattern 375 may be disposed to overlap the second color filter 360 in the non-emission area NLA.

The third color filter 370 may selectively allow the first color light (e.g., blue light) to pass therethrough, and block or absorb the second color light (e.g., red light) and the third color light (e.g., green light). In an embodiment, the third color filter 370 may be a blue color filter and may include a blue colorant such as blue dye or blue pigment, for example.

As described above, the first to third color filters 350, 360, and 370 and the first to third color patterns 355, 365, and 375 may overlap in the non-emission area NLA to block or absorb light. In an embodiment, the first color pattern 355, the second color filter 360, and the third color filter 370 may overlap in the non-emission area NLA disposed to one side of the second emission area LA2, and the first color filter 350, the second color filter 360, and the third color pattern 375 may overlap in the non-emission area NLA disposed to an opposite side of the second emission area LA2, for example.

A first overcoat layer 380 may be disposed on the first to third color filters 350, 360, and 370 and the first to third color patterns 355, 365, and 375. The first overcoat layer 380 may improve the attachment reliability of the optical functional layer LFL, which will be described later, by flattening the upper portion of the color filter layer CFL.

The first overcoat layer 380 may include or consist of an organic material. In an embodiment, the first overcoat layer 380 may include acrylic resin, methacrylate resin, polyisoprene, imide resin, vinyl resin, epoxy resin, urethane resin, cellulose resin, perylene resin, or the like, for example.

The optical functional layer LFL may be disposed on the first overcoat layer 380. The optical functional layer LFL may be an anti-reflection layer that prevents reflection of external light. The optical functional layer LFL may be attached in the form of a film or may be formed by a coating method. However, the disclosure is not limited thereto, and an anti-fingerprint layer or the like may also be disposed.

The low refractive layer 320 described above may include the plurality of pores PO and thus have a relatively low adhesion property to the capping layer 300 therebelow, which may cause delamination at the interface. In the illustrated embodiment, the first passivation layer 340 disposed on the low refractive layer 320 may include the plurality of openings 345, so that the low refractive layer 320 and the first color filter 350, and the low refractive layer 320 and the first color pattern 355 may be in direct contact with each other.

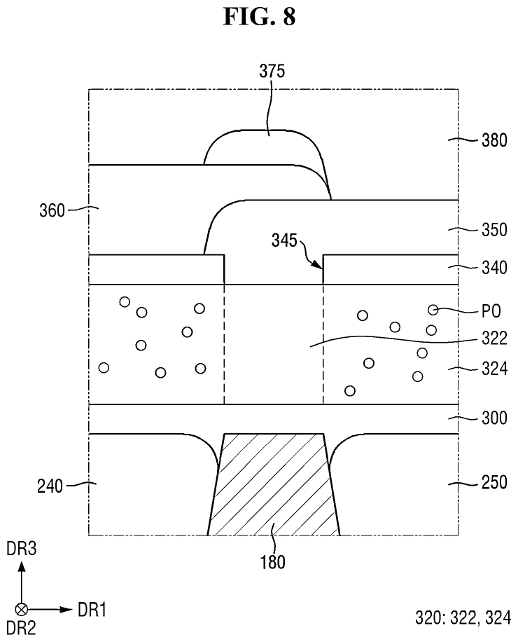

FIGS. 8 to 10 are cross-sectional views showing an embodiment of various structures of a low refractive layer.

Referring to FIGS. 8 to 10 in conjunction with FIG. 3, the low refractive layer 320 may include a first region 322 and a second region 324. The first region 322 of the low refractive layer 320 may be a region that overlaps the opening 345 of the first passivation layer 340, and the second region 324 may be the remaining region excluding the first region 322. The first region 322 may overlap the bank 180 and the non-emission area NLA, and may not overlap the first to third emission areas LA1, LA2, and LA3. The second region 324 may overlap the first to third emission areas LA1, LA2, and LA3. In addition, the first region 322 of the low refractive layer 320 may be in direct contact with the first color filter 350 or the first color pattern 355, and the second region 324 thereof may be spaced apart from the first color filter 350 or the first color pattern 355 to be in non-contact therewith.

The first region 322 of the low refractive layer 320 may not include the pores, and the second region 324 may include the pores PO. In another embodiment, the first region 322 of the low refractive layer 320 may have a smaller amount of pores PO than that of the second region 324.

The first color filter 350 and the first color pattern 355 may be formed by applying a color filter solution onto the first passivation layer 340 in which the plurality of openings 345 is defined through a solution process such as an inkjet method. In this case, the color filter solution may diffuse into the first region 322 of the low refractive layer 320 exposed through the plurality of openings 345. That is, the color filter solution may diffuse into the first region 322 of the low refractive layer 320 to fill the pores PO, thereby removing the pores PO in the first region 322. The color filter solution diffused in the first region 322 of the low refractive layer 320 is cured during the curing process of the color filter layer CFL and acts as the low refractive layer 320. Accordingly, the pores PO in the first region 322 of the low refractive layer 320 may be removed, thereby improving the adhesion property to the capping layer 300 therebelow.

The first region 322 of the low refractive layer 320 may include or consist of components of the color filter solution as the color filter solution diffuses. The first region 322 of the low refractive layer 320 may include the same material as that of the first color filter 350, and may include an organic material and colorant of the first color filter 350, for example.

As shown in FIG. 8, the lateral side of the first region 322 of the low refractive layer 320 may be aligned with the lateral side of the opening 345 of the first passivation layer 340. In an embodiment, the lateral side of the first region 322 and the lateral side of the opening 345 of the first passivation layer 340 may be perpendicular to the substrate SUB along the third direction DR3, for example.

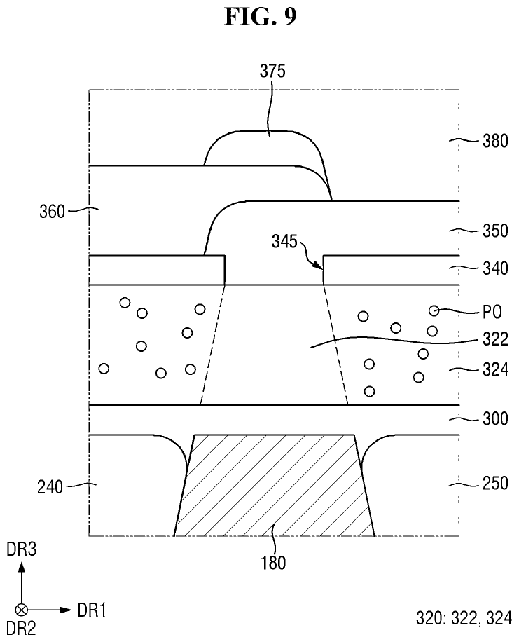

As shown in FIG. 9, in another embodiment, the width of the first region 322 of the low refractive layer 320 may increase toward the substrate SUB. In this structure, as the amount of the color filter solution increases, the amount thereof permeating the low refractive layer 320 increases, so the width of the first region 322 may increase toward the bottom of the first region 322. The width of the top surface of the first region 322 may be the same as the width of the opening 345 of the first passivation layer 340, and the width of the bottom surface of the first region 322 may be greater than the width of the opening 345 of the first passivation layer 340. In addition, the width of the top surface of the first region 322 may be smaller than the width of the bottom surface of the first region 322. As the width of the bottom surface of the first region 322 increases, the pores in the low refractive layer 320 may be removed from a larger area at the interface in contact with the capping layer 300, so that the interfacial adhesion property may be improved.

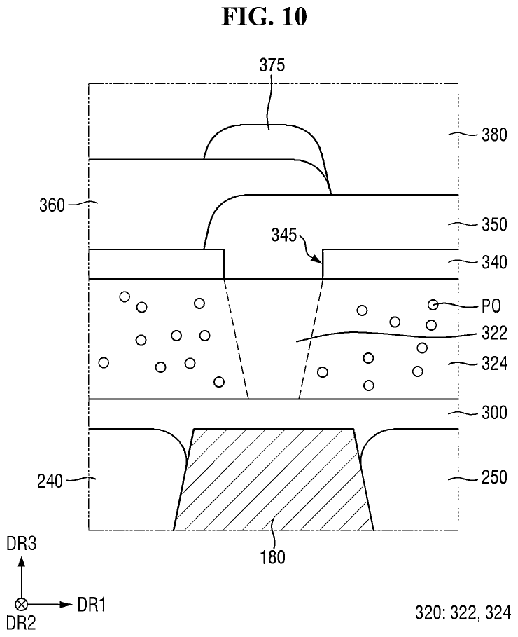

As shown in FIG. 10, in another embodiment, the width of the first region 322 of the low refractive layer 320 may decrease toward the substrate SUB. In this structure, as the amount of the color filter solution decreases, the amount thereof permeating the low refractive layer 320 also decreases, so the width of the first region 322 may decrease toward the bottom of the first region 322. The width of the top surface of the first region 322 may be the same as the width of the opening 345 of the first passivation layer 340, and the width of the bottom surface of the first region 322 may be smaller than the width of the opening 345 of the first passivation layer 340. In addition, the width of the top surface of the first region 322 may be greater than the width of the bottom surface of the first region 322.

As described above, in the illustrated embodiment, the opening 345 of the first passivation layer 340 may be formed on the low refractive layer 320 to bring the low refractive layer 320 into contact with the first color filter 350 and the first color pattern 355, thereby removing the pores in the low refractive layer 320 and improving the interfacial adhesion property with the capping layer 300.

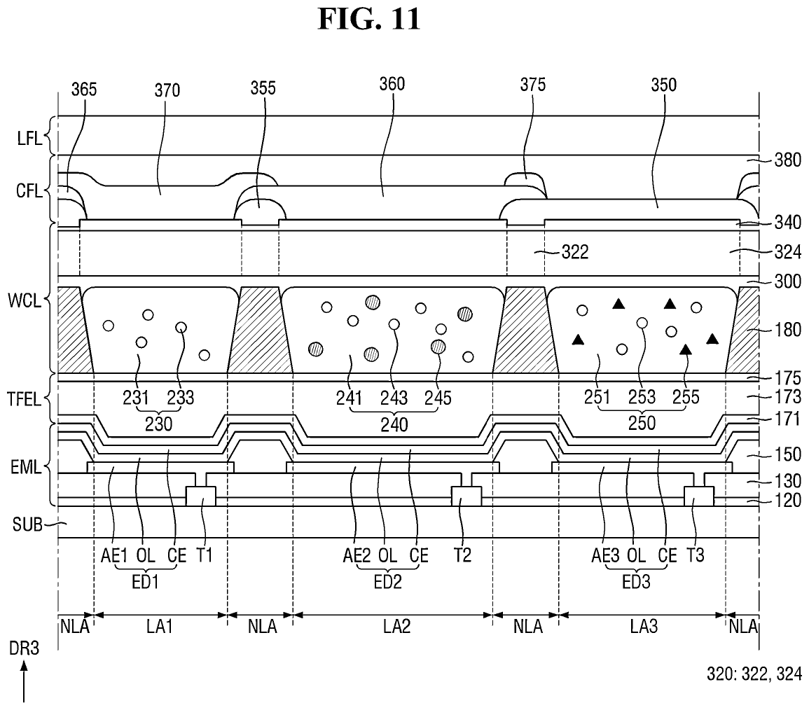

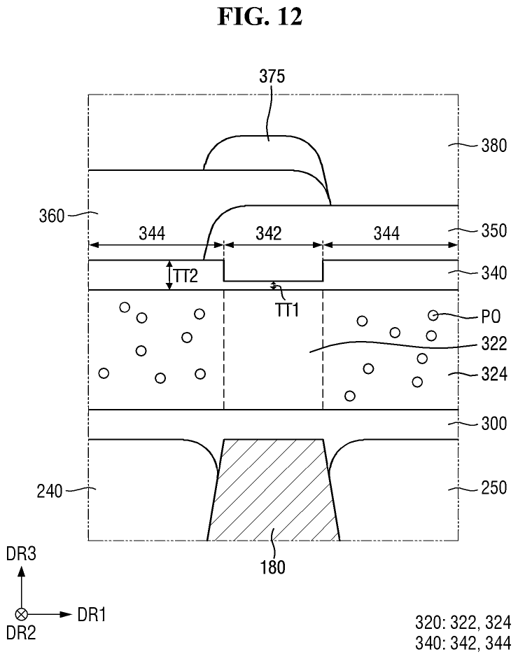

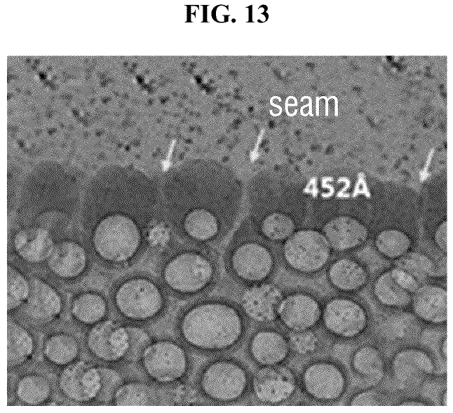

FIG. 11 is a cross-sectional view of an embodiment of a display device. FIG. 12 is an enlarged cross-sectional view of an embodiment of a partial area of the display device of FIG. 11. FIG. 13 is a scanning electron microscope (“SEM”) image of a passivation layer.

Referring to FIGS. 11 and 12, the illustrated embodiment differs from the embodiment of FIGS. 3 to 10 described above in that the first passivation layer 340 includes a first passivation portion 342 and a second passivation portion 344 instead of the plurality of openings. In the following description, redundant description of the above-described embodiments will be omitted while focusing on differences.

The first passivation layer 340 may include the first passivation portion 342 and the second passivation portion 344. The first passivation portion 342 may have a relatively small thickness, and the second passivation portion 344 may have a thickness greater than that of the first passivation portion 342. The first passivation portion 342 may overlap the bank 180 and the non-emission area NLA, and may not overlap the first to third emission areas LA1, LA2, and LA3. The second passivation portion 344 may overlap the first to third emission areas LA1, LA2, and LA3. The arrangement of the first passivation portion 342 is the same as the arrangement of the plurality of openings 345 in the above-described embodiment, and thus description thereof will be omitted.

A thickness TT1 of the first passivation portion 342 may range from about 10 nm to about 100 nm. A thickness TT2 of the second passivation portion 344 may range from about 150 nm to about 1000 nm. The first passivation layer 340 may include a fine seam therein due to the nature of an inorganic layer. When the thickness of the first passivation layer 340 is equal to or greater than a predetermined thickness, no seam may be formed, but when the thickness of the first passivation layer 340 is equal to or less than about 100 nm, a seam may be formed. As shown in FIG. 13, when the first passivation layer 340 is formed to have a thickness of about 452 angstroms (Å), a seam SEAM may be formed.

In the illustrated embodiment, the thickness TT1 of the first passivation portion 342 may be formed in the range of about 10 nm to about 100 nm, allowing for the formation of a seam in the first passivation portion 342. The seam of the first passivation portion 342 may act as a path through which the color filter solution of the first color filter 350 disposed on the first passivation portion 342 may permeate. In this case, the color filter solution may diffuse through the seam of the first passivation portion 342 of the first passivation layer 340 into the low refractive layer 320 therebelow. That is, the color filter solution may diffuse into the pores PO of the low refractive layer 320 to fill the pores PO, thereby removing the pores PO of the low refractive layer 320. The color filter solution diffused in the low refractive layer 320 is cured during the curing process of the color filter layer CFL and acts as the low refractive layer 320. Accordingly, the pores PO of the low refractive layer 320 may be removed, thereby improving the adhesion property to the capping layer 300 therebelow.

The low refractive layer 320 disposed below the first passivation layer 340 may include the first region 322 and the second region 324. The first region 322 of the low refractive layer 320 may be a region that overlaps the first passivation portion 342 of the first passivation layer 340, and the second region 324 may be the remaining region excluding the first region 322 and may overlap the second passivation portion 344.

The first region 322 of the low refractive layer 320 may not include pores as the color filter solution permeates the first region 322 through the first passivation portion 342 of the first passivation layer 340 to remove the pores. The second region 324 of the low refractive layer 320 may include the pores PO. In another embodiment, the first region 322 of the low refractive layer 320 may have a smaller amount of pores PO than that of the second region 324.

As described above, in the illustrated embodiment, the first passivation portion 342 with a relatively small thickness may be formed in the first passivation layer 340, and the pores in the first region 322 of the low refractive layer 320 overlapping the first color filter 350 and the first color pattern 355 in the non-emission area NLA may be removed, thereby improving the interfacial adhesion property with the capping layer 300.

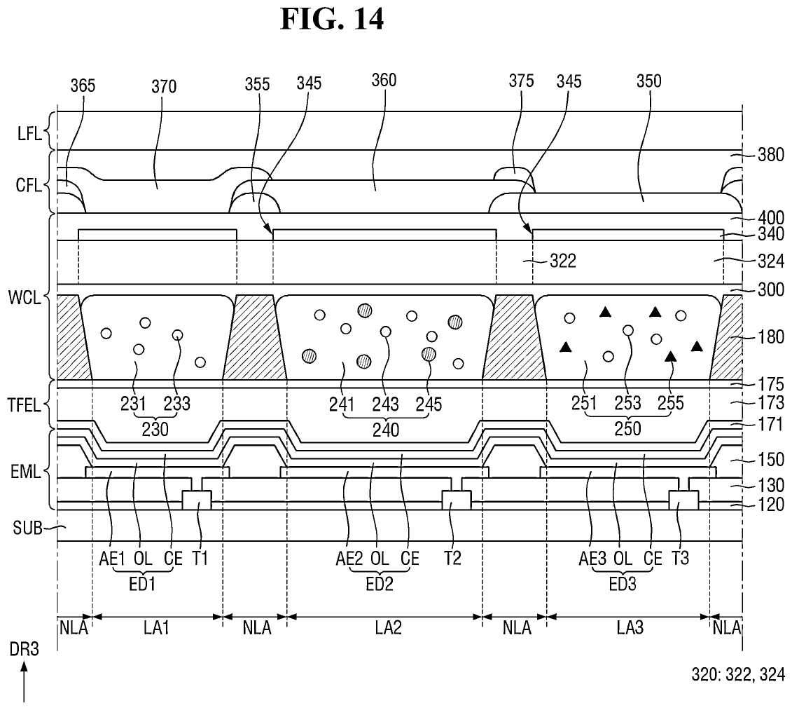

FIG. 14 is a cross-sectional view showing another embodiment of a display device.

Referring to FIG. 14, the illustrated embodiment differs from the embodiments of FIGS. 5 to 13 described above in that it further includes a second overcoat layer 400.

The second overcoat layer 400 may be disposed between the first passivation layer 340 and the color filter layer CFL. The second overcoat layer 400 may be disposed on the first passivation layer 340 to cover the first passivation layer 340. The second overcoat layer 400 may be in direct contact with the low refractive layer 320 through the plurality of openings 345 of the first passivation layer 340. The second overcoat layer 400 may serve to flatten the stepped portions of the first passivation layer 340 and diffuse into the low refractive layer 320 to remove the pores.

The second overcoat layer 400 may be formed by applying an overcoat solution onto the first passivation layer 340 in which the plurality of openings 345 is defined through a solution process such as an inkjet method. In this case, the overcoat solution may diffuse into the first region 322 of the low refractive layer 320 exposed through the plurality of openings 345. That is, the overcoat solution may diffuse into the first region 322 of the low refractive layer 320 to fill the pores PO, thereby removing the pores PO in the first region 322. The overcoat solution diffused in the first region 322 of the low refractive layer 320 is cured during the curing process of the second overcoat layer 400 and acts as the low refractive layer 320. Accordingly, the pores PO in the first region 322 of the low refractive layer 320 may be removed, thereby improving the adhesion property to the capping layer 300 therebelow.

The first region 322 of the low refractive layer 320 may include or consist of components of the overcoat solution as the overcoat solution diffuses. The first region 322 of the low refractive layer 320 may include the same material as that of the second overcoat layer 400, and may include an organic material of the second overcoat layer 400, for example.

The second overcoat layer 400 may be applied between the first passivation layer 340 and the color filter layer CFL in the embodiment of FIGS. 11 and 12 described above.

As described above, in the illustrated embodiment, the second overcoat layer 400 may be further included and be brought into contact with the low refractive layer 320, thereby removing the pores in the low refractive layer 320 and improving the interfacial adhesion property with the capping layer 300.

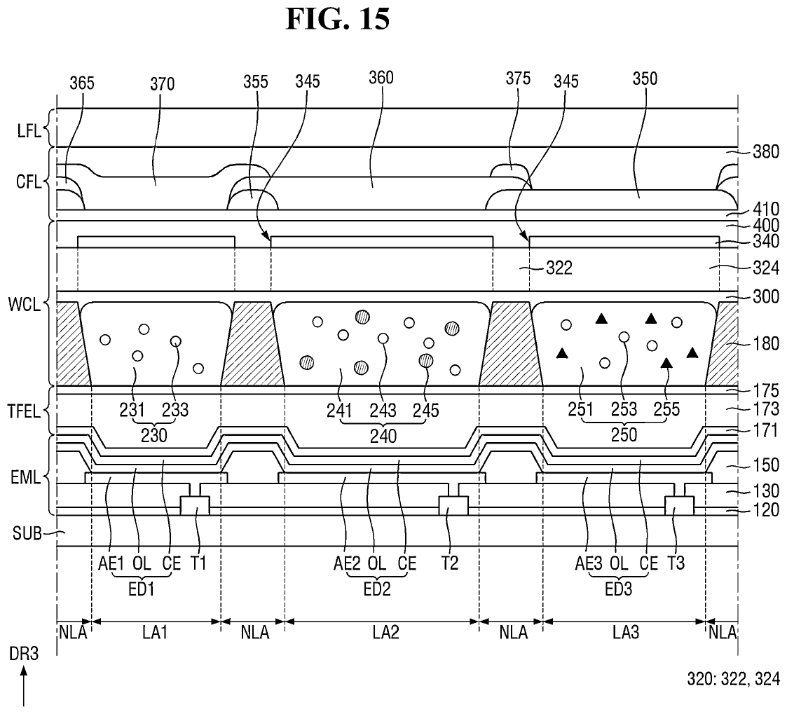

FIG. 15 is a cross-sectional view showing another embodiment of a display device.

Referring to FIG. 15, the illustrated embodiment differs from the embodiment of FIG. 14 described above in that it further includes a second passivation layer 410 on the second overcoat layer 400.

The second passivation layer 410 may be disposed between the second overcoat layer 400 and the color filter layer CFL. The second passivation layer 410 may cover the second overcoat layer 400 to prevent contamination and damage to the second overcoat layer 400.

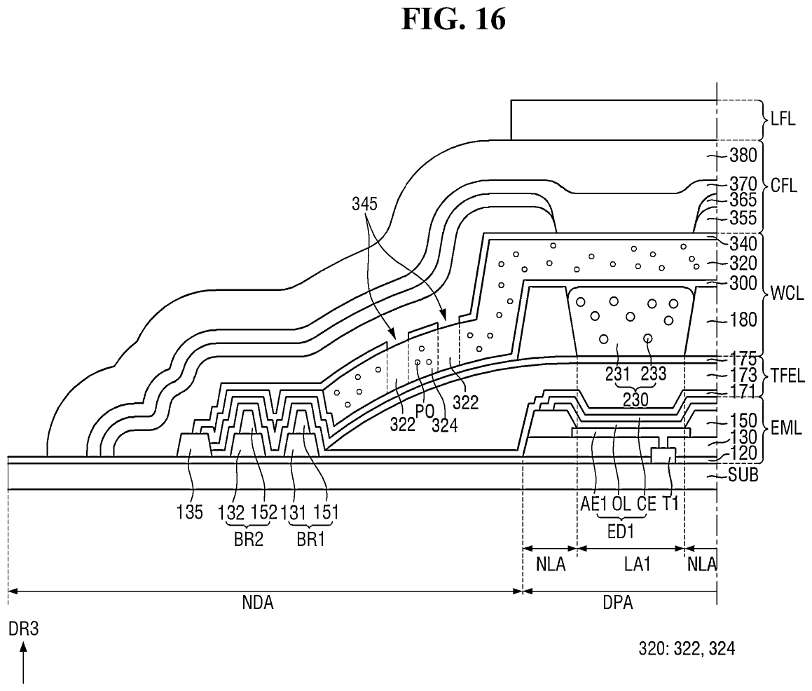

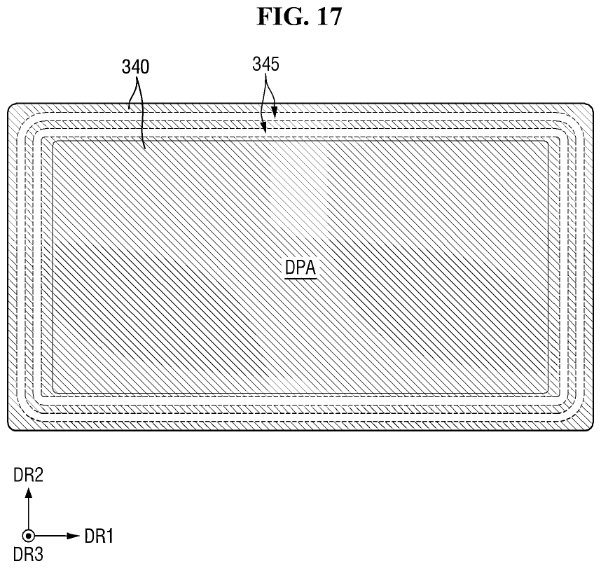

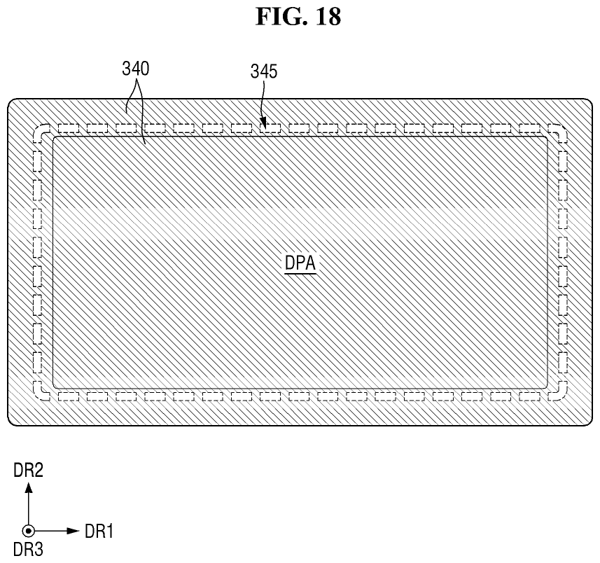

FIG. 16 is a cross-sectional view showing another embodiment of a display device. FIGS. 17 and 18 are plan views showing various embodiments of a display device. FIG. 16 shows the display area DPA and the non-display area NDA of the display device 10 of FIG. 3.

Referring to FIGS. 16 to 18, the illustrated embodiment differs from the embodiments of FIGS. 3 to 15 described above in that the plurality of openings 345 are disposed in the first passivation layer 340 in the non-display area NDA, and the first region 322 and the second region 324 are disposed in the low refractive layer 320. Hereinafter, the redundant description will be omitted and differences will be described.

In the non-display area NDA of the display device 10, a plurality of partition walls BR1 and BR2 and a support 135 may be formed in addition to a plurality of layers extending from the display area DPA.

Specifically, the first insulating layer 120 extending from the display area DPA may be disposed on the substrate SUB in the non-display area NDA. The first insulating layer 120 may be disposed to extend to the lateral side of the substrate SUB. The lateral side of the substrate SUB and the lateral side of the first insulating layer 120 may be aligned with each other.

The plurality of partition walls BR1 and BR2 may be disposed on the first insulating layer 120. The plurality of partition walls BR1 and BR2 may prevent overflow of the encapsulation organic layer 173 of the thin film encapsulation layer TFEL extending from the display area DPA.

The plurality of partition walls BR1 and BR2 may include a first partition wall BR1 adjacent to the display area DPA and a second partition wall BR2 spaced apart from the first partition wall BR1 in a direction toward the lateral side of the substrate SUB.

The first partition wall BR1 may have a multilayer structure in which a first lower layer 131 and a first upper layer 151 are stacked. The first lower layer 131 may include the same material as that of the second insulating layer 130 of the display area DPA. The first lower layer 131 may be formed through the same mask process as the second insulating layer 130. The first lower layer 131 may be disposed directly on the first insulating layer 120. The first upper layer 151 may be disposed on the first lower layer 131 and may include the same material as that of the pixel defining layer 150. The first upper layer 151 may be formed using the same mask process as the pixel defining layer 150.

The second partition wall BR2 may have a multilayer structure in which a second lower layer 132 and a second upper layer 152 are stacked. The second lower layer 132 may include the same material as that of the second insulating layer 130 of the display area DPA and the first lower layer 131. The second lower layer 132 may be formed through the same mask process as the second insulating layer 130 and the first lower layer 131. The second lower layer 132 may be disposed directly on the first insulating layer 120. The second upper layer 152 may be disposed on the second lower layer 132 and may include the same material as that of the pixel defining layer 150 and the first upper layer 151. The second upper layer 152 may be formed through the same mask process as the pixel defining layer 150 and the first upper layer 151.

The support 135 may be disposed on the first insulating layer 120. The support 135 may be disposed between the second partition wall BR2 and the lateral side of the substrate SUB. The support 135 may serve to support a mask for forming the first encapsulation inorganic layer 171 and the second encapsulation inorganic layer 175 of the thin film encapsulation layer TFEL such that the mask may be supported on the substrate SUB. The support 135 may include the same material as that of the second insulating layer 130 of the display area DPA, and may be formed through the same mask process as the second insulating layer 130. However, the support 135 may be omitted.

The plurality of partition walls BR1 and BR2 and the support 135 may be arranged to overlap the color filter layer CFL in the non-display area NDA.

In the drawing, the bank 180 is shown as being disposed in the display area DPA, but the disclosure is not limited thereto, and the bank 180 may be disposed to extend to the non-display area NDA. In an embodiment, the bank 180 may extend to the first partition wall BR1. Additionally, when a dummy pixel is disposed in the non-display area NDA, the bank 180 may also be disposed on top of the dummy pixel.

The thin film encapsulation layer TFEL of the display area DPA may extend and be disposed in the non-display area NDA. The first encapsulation inorganic layer 171 of the thin film encapsulation layer TFEL may extend to the non-display area NDA and be disposed on the first and second partition walls BR1 and BR2. The first encapsulation inorganic layer 171 may cover the first and second partition walls BR1 and BR2. The first encapsulation inorganic layer 171 may extend to the lateral side of the support 135, but is not limited thereto and may cover the support 135. Additionally, the encapsulation organic layer 173 of the thin film encapsulation layer TFEL may extend to the non-display area NDA and be disposed adjacent to the first partition wall BR1. The encapsulation organic layer 173 may be disposed on the first encapsulation inorganic layer 171 to be spaced apart from the first partition wall BR1. The second encapsulation inorganic layer 175 of the thin film encapsulation layer TFEL may extend to the non-display area NDA and be disposed on the first and second partition walls BR1 and BR2. The second encapsulation inorganic layer 175 may be disposed on and cover the first and second partition walls BR1 and BR2. The second encapsulation inorganic layer 175 may extend to the lateral side of the support 135, but is not limited thereto and may cover the support 135.

Some layers of the wavelength conversion layer WCL may extend from the display area DPA and be disposed on the substrate SUB in the non-display area NDA.

The capping layer 300 may extend from the display area DPA and be disposed on the substrate SUB in the non-display area NDA. The capping layer 300 may be disposed to extend from the display area DPA to the support 135. The capping layer 300 may protect the display area DPA from moisture or oxygen that may permeate from the outside.

The low refractive layer 320, the first passivation layer 340, the color filter layer CFL, and the first overcoat layer 380 may extend from the display area DPA and be disposed on the substrate SUB in the non-display area NDA. The low refractive layer 320 may be disposed to extend to the first partition wall BR1, and the first passivation layer 340 may be disposed to extend to the support 135. The color filter layer CFL may extend to be adjacent to the lateral side of the substrate SUB beyond the support 135. The first overcoat layer 380 may extend to be adjacent to the lateral side of the substrate SUB while covering the color filter layer CFL. The first passivation layer 340 may be disposed on the low refractive layer 320, the first color pattern 355 of the color filter layer CFL may be disposed on the first passivation layer 340, and the first overcoat layer 380 may be disposed on the color filter layer CFL. Although the first color pattern 355 is shown in the drawing, the disclosure is not limited thereto, and the first color filter 350 may be disposed instead of the first color pattern 355.

In an embodiment, the first passivation layer 340 may include the plurality of openings 345. The plurality of openings 345 may penetrate the first passivation layer 340 to expose the low refractive layer 320 therebelow. The plurality of openings 345 may be disposed in the non-display area NDA of the display device 10. In an embodiment, the plurality of openings 345 may be disposed between the lateral side of the bank 180 and the plurality of partition walls BR1 and BR2, for example.

As shown in FIG. 17, the plurality of openings 345 may be formed to surround the display area DPA in the non-display area NDA. In an embodiment, the plurality of openings 345 may have a closed loop shape in a plan view, for example. In the drawing, two closed loop-shaped openings 345 are shown, but the disclosure is not limited thereto, and three or more openings 345 may be formed.

Additionally, as shown in FIG. 18, the plurality of openings 345 may be formed in a dot shape surrounding the display area DPA in the non-display area NDA. In this case, the plurality of openings 345 may be defined to be spaced apart from each other.

The low refractive layer 320 may include the first region 322 and the second region 324. The first region 322 of the low refractive layer 320 may be a region that overlaps the opening 345 of the first passivation layer 340, and the second region 324 may be the remaining region excluding the first region 322. The first region 322 and the second region 324 may be disposed in the non-display area NDA. Additionally, the first region 322 of the low refractive layer 320 may be in direct contact with the first color pattern 355 of the color filter layer CFL, and the second region 324 may be spaced apart from the first color pattern 355 of the color filter layer CFL to be in non-contact therewith.

The first region 322 of the low refractive layer 320 may not include the pores, and the second region 324 may include the pores PO. In another embodiment, the first region 322 of the low refractive layer 320 may have a smaller amount of pores PO than that of the second region 324.

The color filter layer CFL may be formed by applying a color filter solution onto the first passivation layer 340 in which the plurality of openings 345 is defined through a solution process such as an inkjet method. In this case, the color filter solution may diffuse into the first region 322 of the low refractive layer 320 exposed through the plurality of openings 345. That is, the color filter solution may diffuse into the first region 322 of the low refractive layer 320 to fill the pores PO, thereby removing the pores PO in the first region 322. The color filter solution diffused in the first region 322 of the low refractive layer 320 is cured during the curing process of the first color pattern 355 and acts as the low refractive layer 320. Accordingly, the pores PO in the first region 322 of the low refractive layer 320 may be removed, thereby improving the adhesion property to the capping layer 300 therebelow.

The first region 322 of the low refractive layer 320 may include or consist of components of the color filter solution as the color filter solution diffuses. The first region 322 of the low refractive layer 320 may include the same material as that of the first color pattern 355, and may include an organic material of the first color pattern 355, for example.

As described above, in the illustrated embodiment, the opening 345 of the first passivation layer 340 may be formed on the low refractive layer 320 in the non-display area NDA to bring the low refractive layer 320 into contact with the first color pattern 355 of the color filter layer CFL, thereby removing the pores in the low refractive layer 320 and improving the interfacial adhesion property with the capping layer 300. In particular, it is possible to further prevent delamination of the interface between the low refractive layer 320 and the capping layer 300 from starting in the non-display area NDA, which is the outer edge of the display device 10.

Although not shown in the drawing, as in the embodiment described with reference to FIGS. 3 to 10, the plurality of openings 345 may also be defined in the first passivation layer 340 in the display area DPA.

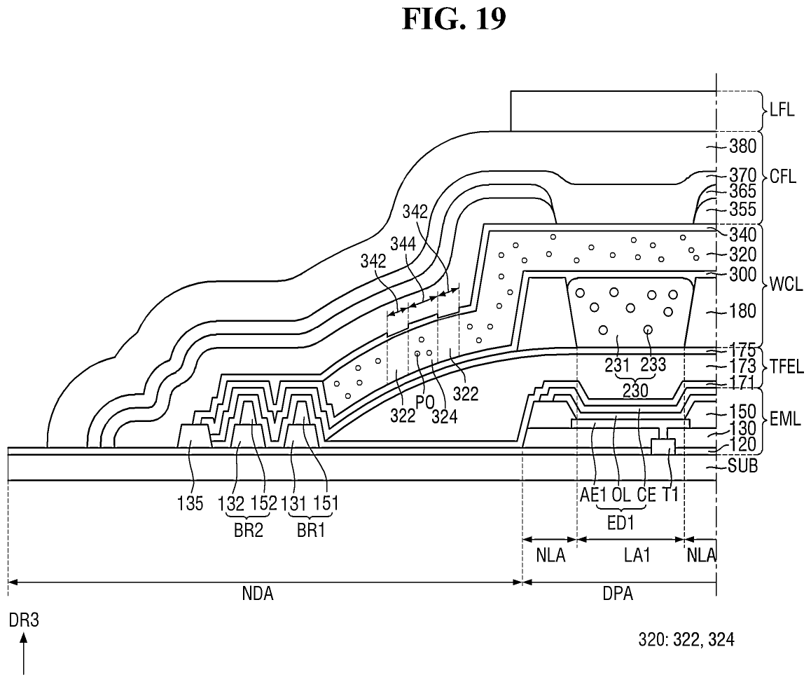

FIG. 19 is a cross-sectional view showing another embodiment of a display device.

Referring to FIG. 19, the illustrated embodiment differs from the embodiment of FIGS. 16 to 18 described above in that the first passivation layer 340 includes the first passivation portion 342 and the second passivation portion 344 instead of the plurality of openings in the non-display area NDA. In the following description, redundant description of the above-described embodiments will be omitted while focusing on differences.

The first passivation layer 340 may include the first passivation portion 342 and the second passivation portion 344. The first passivation portion 342 may have a relatively small thickness, and the second passivation portion 344 may have a thickness greater than that of the first passivation portion 342. The first passivation portion 342 and the second passivation portion 344 may be disposed in the non-display area NDA. The arrangement of the first passivation portion 342 is the same as the arrangement of the plurality of openings 345 in the embodiment of FIGS. 16 to 18 described above, and thus description thereof will be omitted.

The thickness of the first passivation portion 342 may range from about 10 nm to about 100 nm, and the thickness of the second passivation portion 344 may range from about 100 nm to about 1000 nm. In the illustrated embodiment, the thickness TT1 of the first passivation portion 342 may be formed in the range of about 10 nm to about 100 nm, allowing for the formation of a seam in the first passivation portion 342. The seam of the first passivation portion 342 may act as a path through which the color filter solution of the first color pattern 355 of the color filter layer CFL disposed on the first passivation portion 342 may permeate. In this case, the color filter solution may diffuse through the seam of the first passivation portion 342 of the first passivation layer 340 into the low refractive layer 320 therebelow. That is, the color filter solution may diffuse into the pores PO of the low refractive layer 320 to fill the pores PO, thereby removing the pores PO of the low refractive layer 320. Accordingly, the pores PO of the low refractive layer 320 may be removed, thereby improving the adhesion property to the capping layer 300 therebelow.

The low refractive layer 320 disposed below the first passivation layer 340 may include the first region 322 and the second region 324. The first region 322 of the low refractive layer 320 may be a region that overlaps the first passivation portion 342 of the first passivation layer 340, and the second region 324 may be the remaining region excluding the first region 322 and may overlap the second passivation portion 344.

The first region 322 of the low refractive layer 320 may not include pores as the color filter solution permeates the first region 322 through the first passivation portion 342 of the first passivation layer 340 to remove the pores. The second region 324 of the low refractive layer 320 may include the pores PO. In another embodiment, the first region 322 of the low refractive layer 320 may have a smaller amount of pores PO than that of the second region 324.

As described above, in the illustrated embodiment, the first passivation portion 342 with a relatively small thickness may be formed in the first passivation layer 340, and the pores in the first region 322 of the low refractive layer 320 overlapping the first color pattern 355 of the color filter layer CFL in the non-display area NDA may be removed, thereby improving the interfacial adhesion property with the capping layer 300.

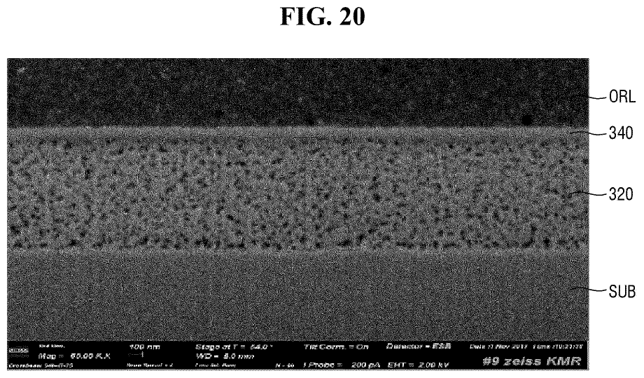

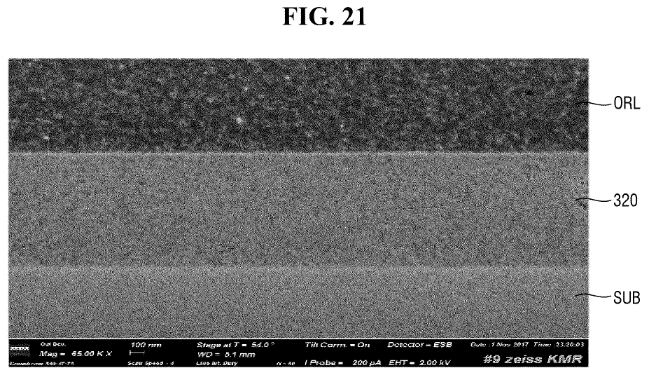

FIG. 20 is an SEM image of a low refractive layer manufactured according to a comparative example. FIG. 21 is an SEM image of a low refractive layer manufactured according to a test example.

In the comparative example, a sample was fabricated by forming the low refractive layer 320 including pores on the substrate SUB, forming the first passivation layer 340 on the low refractive layer 320, and applying an organic coating layer ORL onto the first passivation layer 340.

In the test example, a sample was fabricated under the same conditions as the comparative example, except that the first passivation layer 340 was omitted.

Referring to FIG. 20, in the sample according to the comparative example, many pores were observed in the low refractive layer 320. Referring to FIG. 21, in the sample according to the test example, it was confirmed that the pores in the low refractive layer 320 were removed.

Through this result, it may be seen that when an organic material is coated on the low refractive layer 320, the organic material diffuses into the low refractive layer 320 to remove the pores.

In concluding the detailed description, those skilled in the art will appreciate that many variations and modifications may be made to the preferred embodiments without substantially departing from the principles of the invention. Therefore, the disclosed preferred embodiments of the invention are used in a generic and descriptive sense only and not for purposes of limitation.

What is claimed is:

1. A display device comprising:
a light-emitting element layer disposed on a substrate;
a thin film encapsulation layer disposed on the light-emitting element layer;
a bank disposed on the thin film encapsulation layer, and partitioning emission areas and a non-emission area;
a capping layer disposed on the bank;
a low refractive layer disposed on the capping layer, and comprising pores;
a passivation layer disposed on the low refractive layer, and defining a plurality of openings; and
a color filter layer disposed on the passivation layer,
wherein the low refractive layer overlaps the plurality of openings and comprises first regions and a second region different from the first regions, and
the first regions contact the color filter layer.

2. The display device of claim 1, wherein the first regions overlap the non-emission area, and the second region overlaps the emission areas.

3. The display device of claim 1, wherein the first regions do not comprise the pores and the second region comprises the pores.

4. The display device of claim 1, wherein the first regions have a smaller amount of pores than an amount of pores of the second region.

5. The display device of claim 1, wherein the color filter layer comprises a first color filter overlapping one of the emission areas and a first color pattern overlapping the non-emission area, and
the first regions contact one of the first color filter and the first color pattern.

6. The display device of claim 5, wherein the first regions include an organic material or colorant of one of the first color filter and the first color pattern.

7. The display device of claim 1, wherein the plurality of openings of the passivation layer overlaps the non-emission area.

8. The display device of claim 7, wherein the plurality of openings is defined in a dot shape or mesh shape in a plan view.

9. A display device comprising:
a light-emitting element layer disposed on a substrate;
a thin film encapsulation layer disposed on the light-emitting element layer;
a bank disposed on the thin film encapsulation layer, and partitioning emission areas and a non-emission area;
a capping layer disposed on the bank;
a low refractive layer disposed on the capping layer, and comprising pores;
a passivation layer disposed on the low refractive layer, and comprising a first passivation portion and a second passivation portion having a thickness greater than a thickness of the first passivation portion; and
a color filter layer disposed on the passivation layer,
wherein the low refractive layer overlaps the first passivation portion and comprises first regions which do not comprise the pores and a second region which comprises the pores as a remaining region excluding the first regions.

10. The display device of claim 9, wherein the first passivation portion overlaps the non-emission area, and the second passivation portion overlaps the emission areas.

11. The display device of claim 9, wherein the thickness of the first passivation portion ranges from about 10 nanometers to about 100 nanometers.

12. The display device of claim 9, wherein the color filter layer comprises a first color filter overlapping one of the emission areas and a first color pattern overlapping the non-emission area, and
the first regions overlap one of the first color filter and the first color pattern.

13. A display device comprising:
a light-emitting element layer disposed on a substrate;
a thin film encapsulation layer disposed on the light-emitting element layer;
a bank disposed on the thin film encapsulation layer, and partitioning emission areas and a non-emission area;
a capping layer disposed on the bank;
a low refractive layer disposed on the capping layer, and comprising pores;
a first passivation layer disposed on the low refractive layer, and defining a plurality of openings;
an overcoat layer disposed on the first passivation layer; and
a color filter layer disposed on the overcoat layer,
wherein the low refractive layer overlaps the plurality of openings and comprises first regions and a second region different from the first regions, and
the first regions contact the overcoat layer.

14. The display device of claim 13, wherein the first regions do not comprise the pores and the second region comprises the pores.

15. The display device of claim 13, wherein the first regions have a smaller amount of pores than an amount of pores of the second region.

16. The display device of claim 13, wherein the first regions include an organic material of the overcoat layer.

17. The display device of claim 13, further comprising a second passivation layer disposed between the overcoat layer and the color filter layer.

18. A display device comprising:
a substrate comprising a display area and a non-display area;
a light-emitting element layer disposed on the display area of the substrate;
a thin film encapsulation layer disposed on the light-emitting element layer;
a bank disposed on the thin film encapsulation layer, and partitioning emission areas and a non-emission area;
a capping layer disposed on the bank, and extending to the non-display area;
a low refractive layer disposed on the capping layer, extending from the display area to the non-display area and comprising pores;
a passivation layer disposed on the low refractive layer, and defining a plurality of openings defined in the non-display area;
a color filter layer disposed on the display area and the non-display area of the passivation layer,
wherein the low refractive layer overlaps the plurality of openings and comprises first regions and a second region different from the first regions, and
the first regions contact the color filter layer.

19. The display device of claim 18, wherein the plurality of openings surrounds the display area, and is defined in a line shape or dot shape in a plan view.

20. The display device of claim 18, wherein the first regions do not comprise the pores and the second region comprises the pores.

21. The display device of claim 18, wherein the first regions have a smaller amount of pores than an amount of pores of the second region.

22. The display device of claim 18, wherein the first regions include an organic material of the color filter layer.
